(19) United States
(12) Patent Application Publication
(10) Pub. No.: US 2026/0338323 A1
(43) Pub. Date: Oct. 29, 2026

(54) Mounting Bracket and Display Mounting Bracket

(71) Applicant: Jolly Innovation Technology Co., Ltd., Guangzhou (CN)

(72) Inventor: Li XIAO, Guangzhou (CN)

(21) Appl. No.: 19/536,598

(22) Filed: Feb. 11, 2026

(30) Foreign Application Priority Data
Apr. 23, 2025 (CN) 202520789951.5

(51) Int. Cl. F16M 13/02; F16M 11/10; F16M 11/22; H05K 7/14

(52) U.S. Cl. CPC F16M 13/02; F16M 11/10; F16M 11/22; F16M 13/022; H05K 7/1489

(57) ABSTRACT

The present disclosure provides a display mounting bracket, for mounting a display to a standing object, the display mounting bracket comprising: a base; a mounting plate coupled to the base, and configured to mount the display; the mounting plate is connected to an arm, and the arm rotatably attached to a connecting plate, the connecting plate is opposite the base and detachably connected to the base; and at least two active pieces rotatably attached to the base and configured to directly abut against a surface of the standing object.

### RELATED APPLICATIONS

This application claims the benefit of priority to Chinese Patent Application Number 202520789951.5 filed on Apr. 23, 2025, in the China National Intellectual Property Administration. The entire contents of the above-identified application is hereby incorporated by reference.

### TECHNICAL FIELD

The present application relates to mounting brackets, and especially relates to a mounting bracket for mounting a display device to a standing object, such as, a post, a pole or a wall.

### BACKGROUND ART

The standing objects, for example Poles, are common architectural structures widely found indoors or outdoors. Mountable objects, such as televisions, speakers, artworks, and lamps are needed to be safely mounted onto the standing objects. Sometimes, it is particularly challenging, especially when the objects to be mounted are heavy and large. Furthermore, the standing objects for example the poles may have various sizes and/or shapes, which requires mounting devices for mounting the mountable objects can adapt the various sizes and shapes of the standing objects.

### BRIEF DESCRIPTION OF DRAWINGS

To illustrate technical solutions in embodiments of the present disclosure more clearly, the following briefly introduces accompanying drawings used in the description of the embodiments. Obviously, the accompanying drawings in the following description are only some embodiments of the present disclosure. Those of ordinary skill in the art can obtain other accompanying drawings from these accompanying drawings without any creative efforts.

FIG. 1 is a perspective view of a mounting bracket according to an embodiment of the present disclosure which is mounted on a standing object, such as a post or a pole.

FIG. 2 is a schematic diagram of an installation of the mounting bracket according to the embodiment of the present disclosure.

FIG. 3 is a perspective view of the mounting bracket according to the embodiment of the present disclosure.

FIG. 4 is a perspective view of a base of the mounting bracket according to the embodiment of the present disclosure.

FIG. 5 is a schematic diagram showing a cooperation between the base and a strap according to the embodiment of the present disclosure.

FIG. 6A is a schematic diagram showing the mounting bracket being installed on a cylinder. FIG. 6B is a schematic diagram showing the mounting bracket being installed on a square standing object.

FIG. 7 is a schematic diagram showing an angle between side portion and middle portion of the base.

FIG. 8 is a perspective view of a base from another perspective according to the embodiment of the present disclosure.

FIG. 9 is a schematic diagram of the assembly relationship between a pivot shaft and a winding structure according to the embodiment of the present disclosure.

FIG. 10 is a schematic diagram of the winding structure according to the embodiment of the present disclosure.

FIG. 11 is a schematic diagram of a board and connecting body according to the embodiment of the present disclosure.

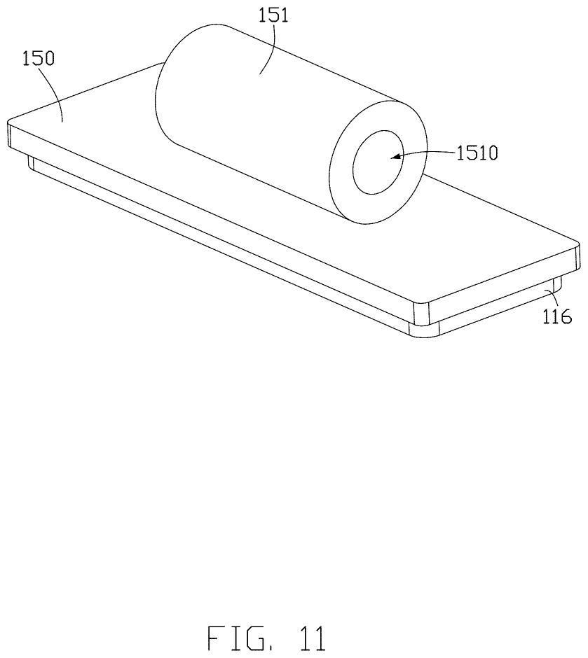

FIG. 12 is a schematic diagram of the connection between an active piece and a pivot shaft according to the embodiment of the present disclosure.

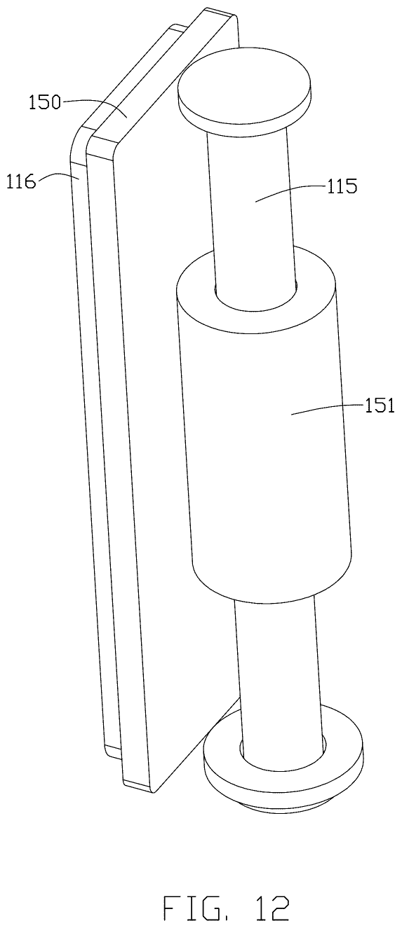

FIG. 13 is a schematic diagram of a display being installed on the mounting bracket according to the embodiment of the present disclosure.

FIG. 14 is a schematic diagram of a mounting bracket according to an embodiment of the present disclosure which is mounted on a square pole.

FIG. 15 is a schematic diagram of a mounting bracket according to an embodiment of the present disclosure which is mounted on a hexagonal pole.

FIG. 16 is a schematic diagram of a mounting bracket according to an embodiment of the present disclosure which is mounted on a triangular pole.

FIG. 17 is a schematic diagram of a mounting bracket according to an embodiment of the present disclosure which is mounted on an I-beam.

### DETAILED DESCRIPTION

Reference will now be made in detail to representative embodiments illustrated in the accompanying drawings. It should be understood that the following descriptions are not intended to limit the embodiments to one preferred implementation. To the contrary, the described embodiments are intended to cover alternatives, modifications, and equivalents as can be included within the spirit and scope of the disclosure and as defined by the appended claims.

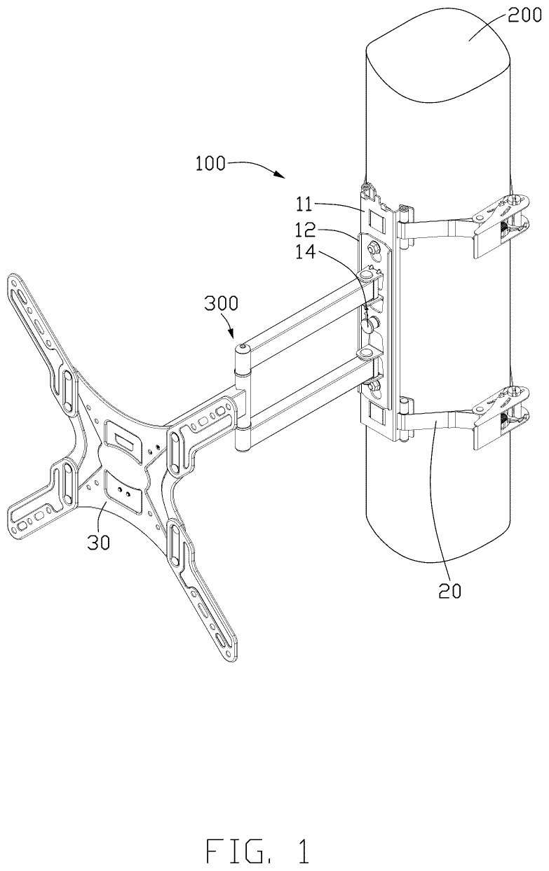

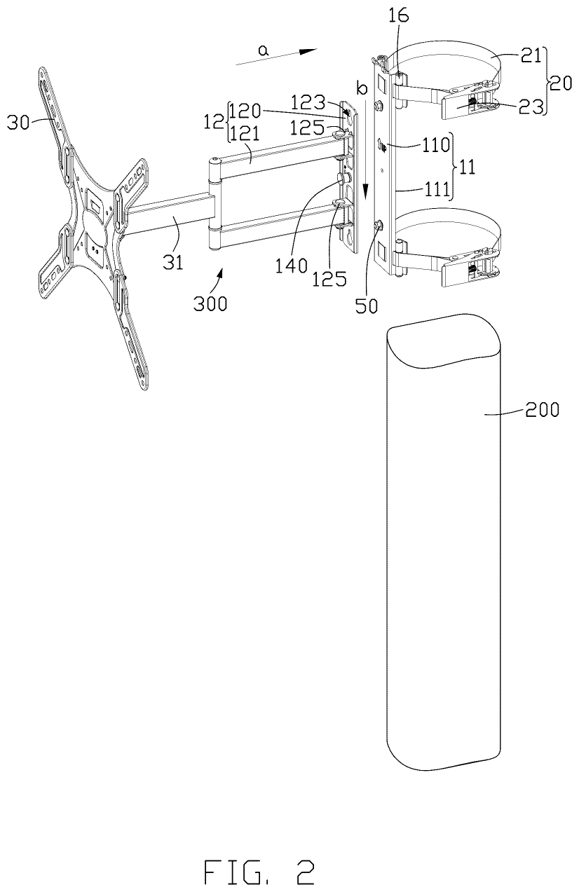

Referring to FIGS. 1 and 2, a mounting bracket 100 is provided for mounting a mountable device to an object. The mountable device may be a display device, (such as a television or computer), a speaker, an artwork, or a lamp. The object may be a standing object such as a wall, a post, or a pole. The mounting bracket 100 includes a base 11, at least one strap 20, a mounting plate 30 and at least two active pieces 15 connecting with the base 11. Each of the at least two active pieces 15 is provided with a board 150 and a connecting body 151. The board 150 is rotatably attached to a side of the base 11 via the connecting body 151 and configured to directly contacts and abuts against a surface of the standing object 200. The at least one strap 20 is configured to bind the base 11 to the standing object 200 and press the at least two active pieces 15 towards the standing object 200. The mounting plate 30 is detachably connected to the other side of the base 11, the other side is opposite to the side which the board 150 is attached to. The mounting plate 30 is configured to mount the mountable device to be installed.

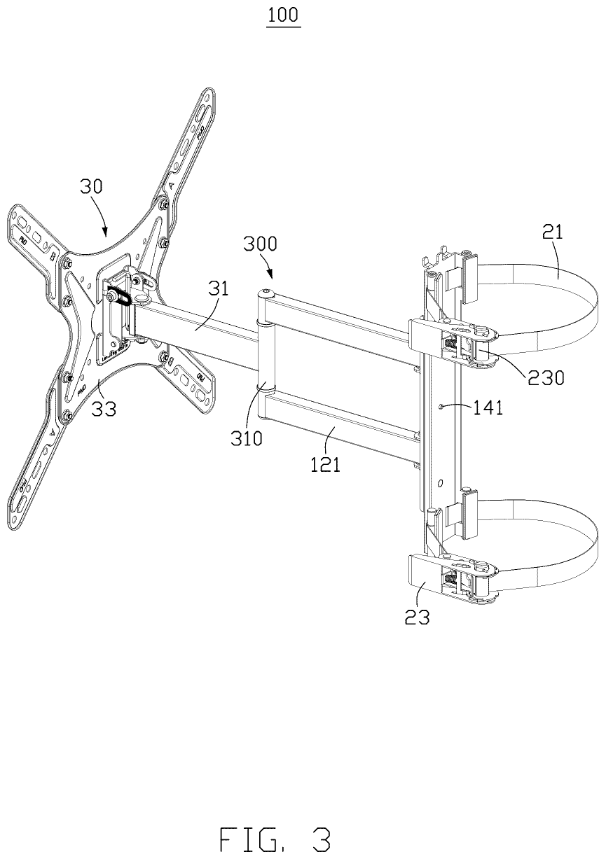

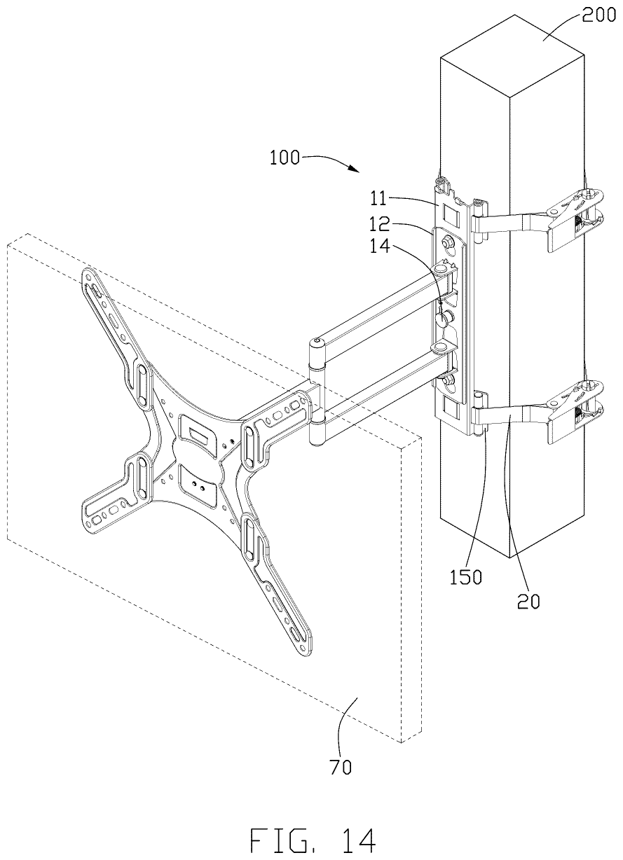

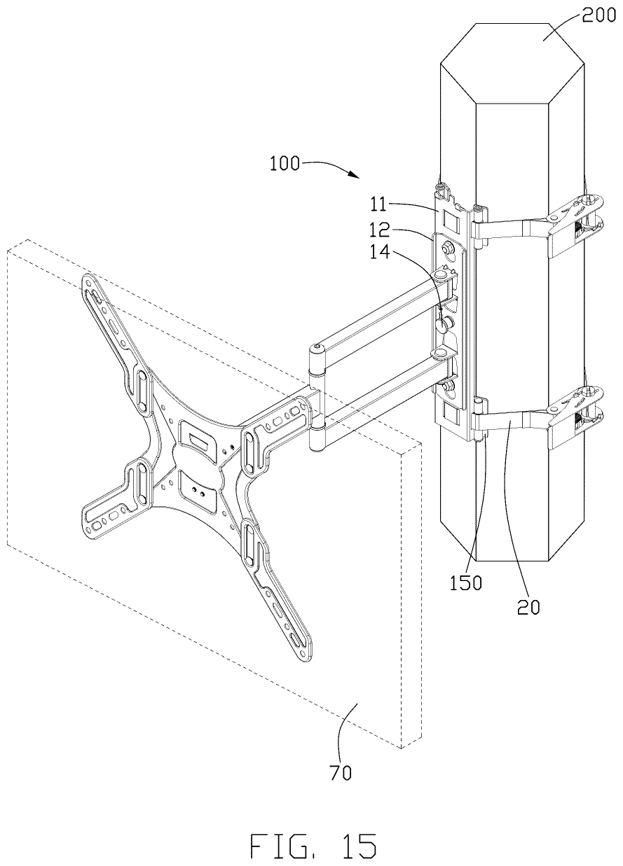

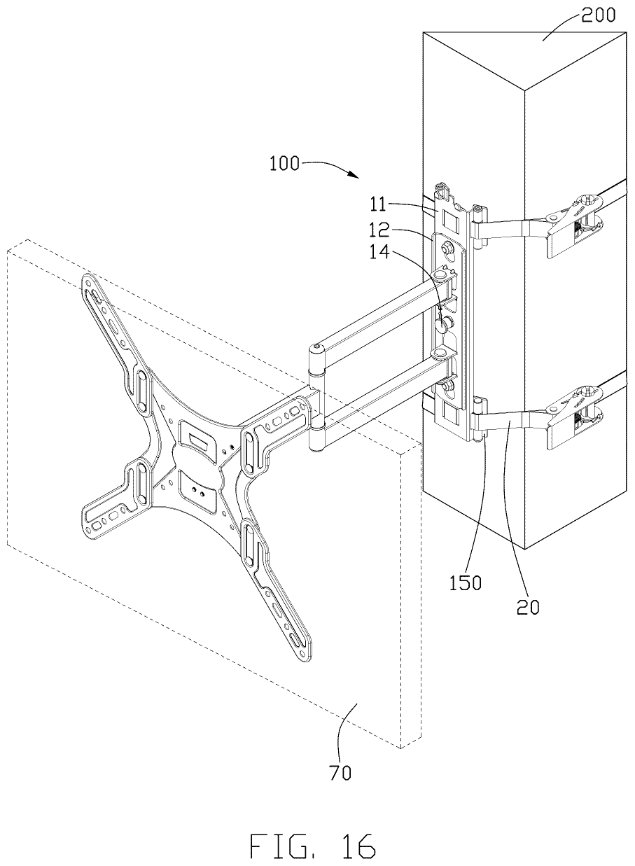

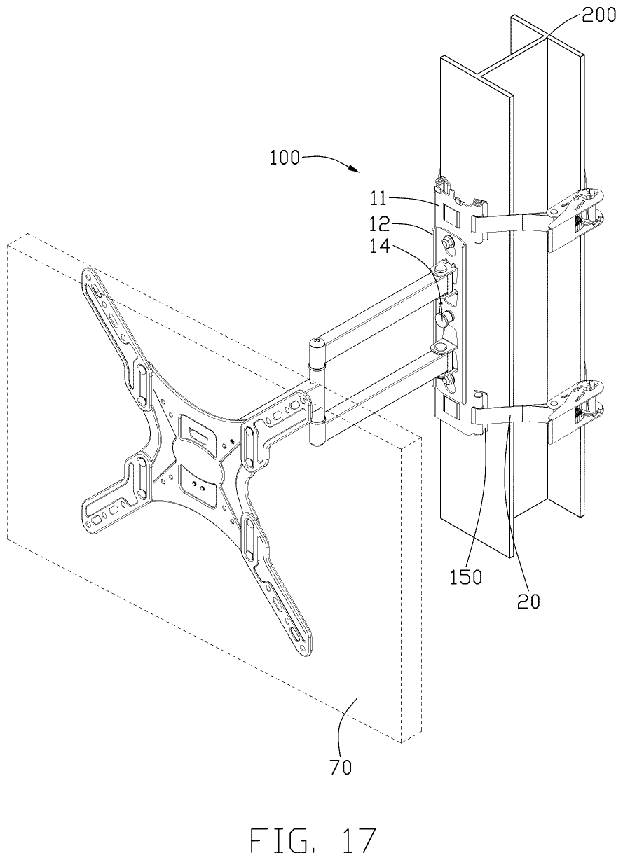

Referring to FIGS. 14 to 17, the standing object 200 may have a shape such as circular, rectangular, triangular, or I-shaped. Each of the at least one strap 20 includes a strap body 21 and a tightener 23 attached to the strap body 21. When the strap body 21 is bound around the standing object 200, a tension force of the strap body 21 can be adjusted via the tightener 23. Referring to FIGS. 1-3, 5, and 6, the strap body 21 is a flexible nylon woven strap, which has advantages such as high strength, good wear resistance, light weight, waterproofing, and flexible bending. Referring to FIG. 3, one end portion of the strap body 21 is fixed to the tightener 23, and the other end portion passes through the tightener 23 and is clamped by a clamping member 230 of the tightener 23 after extending around the pole 200. A tail of the other end portion of the strap body 21 is exposed from the clamping member 230 and can be pulled out relative to the clamping member 230, for allowing adjusting the length of the strap body 21 wrapped around the standing object 200. The shape and structure of the tightener 23 are not limited and may adopt common buckle structures for limiting strap length, such as belt buckle structures or buckle structures from automobile safety belts.

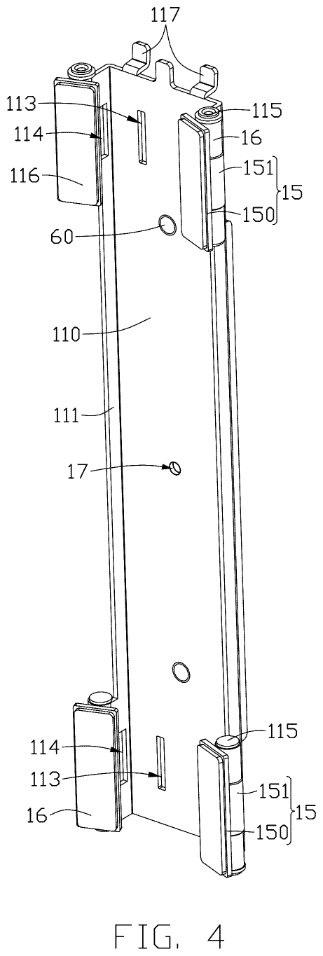

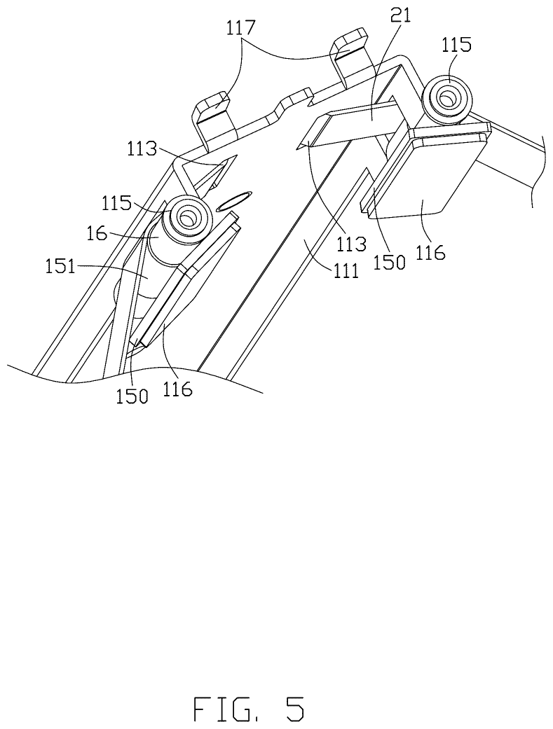

Referring to FIGS. 4,11 and 12, each of the at least two active pieces 15 includes a board 150 and a connecting body 151 fixed to a side surface of the board 150. The connecting body 151 has a pivot hole 1510, and the pivot hole 1510 pivots on the base 11, so as to adjust the position of the board 150 relative to the base 11. The board 150 may be a metal plate, such as a rectangular metal plate. The connecting body 151 may be a hollow shaped tube. An outer wall of the metal plate and an outer wall of the tube are integrated by welding. Referring to FIGS. 5,11 and 12, a contacting surface of the board 150 that contacts the standing object 200 is covered by a pad 116. The pad 116 is made by a material which has a hardness less than a hardness of a material of the board 150. In an embodiment, the board 150 is made by metal, and the pad 116 is made by rubber. The pad 116 is configured to increase frictions between the board 150 and an outer surface of the standing object 200. It is understandable that protrusions may also be provided on the board 150 and/or pad 116 to increase the frictions.

Referring to FIG. 3, the mounting plate 30 is connected to an arm 300, the arm 300 rotatably attached to the connecting plate 120. The arm 300 includes a first arm 31 and a second arms 121. The first arm 31 is hinged to a second arms 121 via a hinged shaft sleeve 310. The second arms 121 are hinged to the connecting plate 120 which is opposite the base 11 and detachably connected to the base 11. A detachable connection is a design allowing repeated assembly and disassembly between two or more components, such as threaded connections, buckle connections, pin connections, magnetic connections, etc. The connecting plate 120 and the second arms 121 together form connection mechanism 12. The shape and structure of the mounting plate 30 are not particularly limited and can be designed in various shapes and structures, as long as the mounting plate 30 can secure televisions, speakers, artworks, lamps, etc.

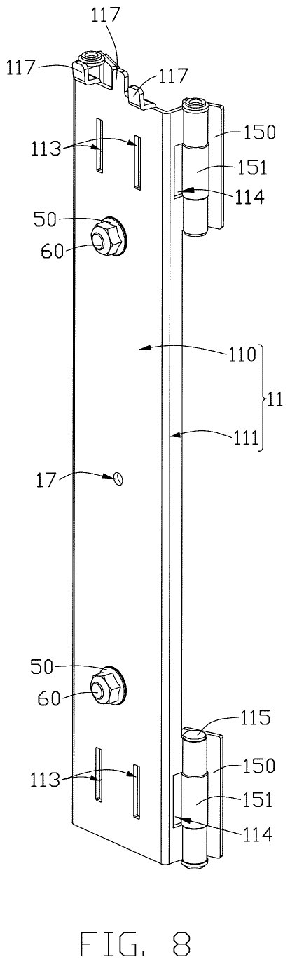

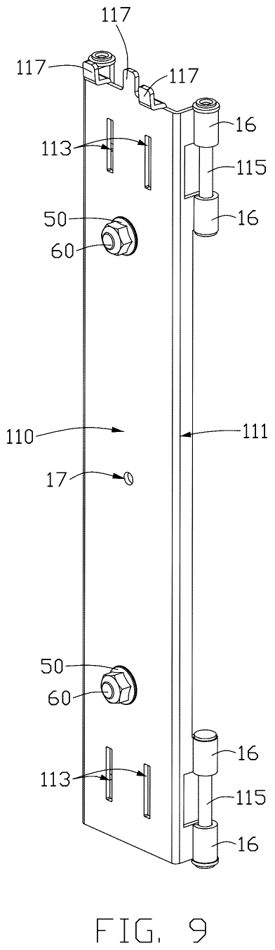

Referring to FIG. 1, the base 11 is fixed upright on the standing object 200. Referring to FIGS. 8 and 9, the base 11 includes a middle portion 110 and two side portions 111 connecting with opposite sides of the middle portion 110. The middle portion 110 is a main plate which has an elongated rectangular shape and two side portions 111 may be two side plates bent from left and right side edges of the main plate 110. A screw 60 passes through the main plate 110 from a surface (which is a surface connected to the connecting plate 120) of the middle portion 110 facing away from the standing object 200. A nut 50 is threadedly connected to the screw 60. The screw 60 and the nut 50 are threadedly engaged to fix the connecting plate 120 and the base 11 together. The nut 50 may be a flange nut, so as to improve a contact area between the nut 50 and the base 11, thereby enhancing the reliability of the fixation of the base 11 by the nut 50.

Referring to FIGS. 4,7 and 10, a plurality of winding structures 16 are formed on the upper side and the lower side of the main plate 110. Each winding structure 16 is wound towards outside. These winding structure 16 are used for installing pivot shafts 115. These winding structures 16 are wound-shaped and are located at four corner positions of the base 11. Each winding structure 16 includes an upper portion and a lower portion spaced from the upper portion, with a notch 1141 formed between the upper portion and the lower portion. The upper and lower portions are provided with coaxial through holes 161. A pivot shafts 115 is inserted into the winding structure 16 and passes through the through holes 161 in the upper and lower portions so as to be fixed in the winding structure 16. The connecting body 151, which is fixedly connected to the board 150, is coaxially sleeved on the pivot shafts 115 (e.g., a hollow rivet) and can pivot about the pivot shafts 115 relative to the base 11. The connecting body 151 is located between the upper and lower portions. The winding structure 16 directly formed on the side portion 111 so that the manufacturing process may be simplified This winding structure 16, integrally formed with the base 11, can improve structural strength and overall stability.

In some embodiments, besides using the winding structure 16 to install a pivot shafts 115 to achieve rotation of the board 150, other structural forms are possible. For example, a hinge may be fixed to the side portion 111, and the board 150 may then be installed on the hinge, enabling the board 150 to rotate relative to the base 11. Whether the winding structure 16 or a hinge or other structure, the essence is to form a rotation mechanism, for which multiple implementation methods exist in related technologies.

Referring to FIGS. 3 and 4, in some embodiments, upper and lower ends of the main portion 110 are each provided with a pair of elongated first hole 113. Each pair of the first hole 113 is arranged parallel and spaced apart, for the strap body 21 to pass through. Furthermore, an upper end and a lower end of each side portion 111 are provided with an elongated second hole 114. The first hole 113 at the upper end of the middle portion 110 and the second hole 114 at the upper end of the side portion 111 are located at the same height on the base 11, allowing one strap body 21 to pass. The first hole 113 at the lower end of the middle portion 110 and the second hole 114 at the lower end of the side portion 111 are located at the same height on the base 10, allowing another strap 20 to pass. The two straps 20 can firmly bind the mounting bracket 100 to the standing object 200. The board 150 is located on a side of the second hole 114 close to the standing object 200. When the strap body 21 sequentially passes through the first hole 113 and the second hole 114, the strap body 21 presses against the connecting body 151.

Referring to FIGS. 1 and 5, the strap body 21 sequentially passes through the second hole 114 on one side portion 111, the first hole 113 on the middle portion 110, and the second hole 114 on another side portion 111, ultimately wrapping around the standing object 200. When the strap body 21 passes through the second hole 114, the strap body 21 directly presses against the connecting body 151, the connecting body 151 can reliably attach to the surface of the standing object 200. When the connecting body 151 selects the hollow shaped tube, the connecting body 151 can reduce wear on the strap body 21.

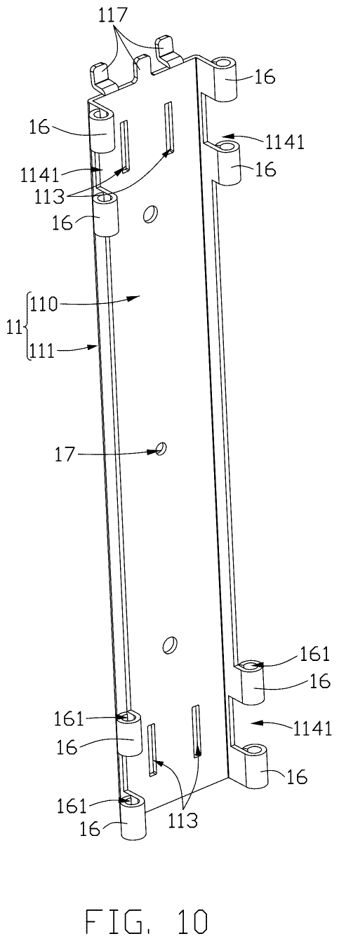

Moreover, with reference to FIGS. 8 to 10, the second hole 114 is not directly machined on the side portion 111. In fact, the second hole 114 is formed after the active piece 15 is installed on the winding structure 16, or in other words, the second hole 114 is formed at the position of the notch 1141 after the pivot hole 1510 is sleeved over the pivot shafts 115.

In some embodiments, by making the rotational resistance of the connecting body 151 very small (For example, add lubricant into pivot hole 1510), the rotation of the board 150 can be made adaptive. Therefore, when the strap body 21 is tightened, the strap body 21 presses against the connecting body 151, naturally pushing the board 150 to rotate until the board 150 tightly contacts the surface of the standing object 200. The adaptive rotation characteristic of the board 150 ensures that a plane of the board 150 always forms a large-area, stable contact with a surfaces of standing object 200 of different shapes, thereby generating maximum static friction and effectively preventing the base 11 from sliding or shifting. The board 15 does not necessarily have to be adaptively rotatable; the board 150 can also be manually rotated. For example, before tightening the strap body 21, the board 150 can be manually rotated to a suitable angle to make the board 150 adhere to the surface of the standing object 200.

Referring to FIG. 4, in some embodiments, a top end of the middle portion 110 is further provided with a storage feature 117. The storage feature 117 is configured to hold installation and adjustment tools, such as a wrench or screwdriver for turning the nut 50. The storage feature 117 may be a lug structure, a through-hole structure, a groove structure, etc.

Referring to FIG. 2, in some embodiments, the base 11 and the connecting plate 120 are both elongated. A length of the connecting plate 120 is less than a length of the base 11. When the connecting plate 120 is connected to the base 11, the connecting plate 120 fits against the base 11, and the connecting plate 120 is located between the two straps 20. This prevents the connecting plate 120 from contacting the strap body 21 and causing wear to the strap body 21. The connecting plate 120 is formed with more than two connecting tabs 125. Each connecting tab 125 extends vertically bent from a surface of the connecting plate 120 toward the mounting plate 30. One end of the second arms 121 is pivotally connected between a pair of connecting tabs 125 by a connector such as a pin. There are multiple ways to fix the connecting plate 120 and the connecting tabs 125 together, such as welding, riveting and so on.

In some embodiments, the mounting plate 30 and the base 11 are connected via the screw 60 and the nut 50. The connecting plate 120 is provided with a keyhole slot 123 for the screw 60 to pass through. Referring to FIGS. 1 and 2, upper and lower ends of the connecting plate 120 are respectively provided with a keyhole slot 123 (gourd-shaped hole). Each keyhole slot 123 includes a large arc hole and a small arc hole. The small arc hole is above, and the large arc hole is below. The small arc hole and the large arc hole are connected to form a complete keyhole slot 123. An inner diameter of the large arc hole is made larger than an outer diameter of the nut 50. When connecting the connecting plate 120 to the base 11, the screw 60 is first passed through the large arc hole of the keyhole slot 123. Then, the connecting plate 120 is pressed down along the length direction of the base 11, causing the nut 50 to move into the small arc hole of the keyhole slot 123. Finally, the nut 50 on the screw 60 is tightened, firmly fixing the connecting plate 120 to the base 11 through the nut 50. The process is simple and quick. This cooperative design of the keyhole slot 123 and the screw 60 allows the connecting plate 120 to be initially hooked and positioned onto the base 11 without any tools, greatly reducing the installation difficulty for a single operator. Subsequent tightening via the nut 50 enables a smooth transition from quick installation to reliable locking.

By making the inner diameter of the large arc hole greater than the outer diameter of the nut 50, the nut 50 can remain threadedly connected to the screw 60 without separation. That is, when connecting the connecting plate 120 to the base 11, it is not necessary to first unscrew the nut 50 from the screw 60. Instead, the nut 50 remains threadedly connected to the screw 60, only initially loosened to create a gap between the nut 5 and the base 11. This gap is greater than the thickness of the connecting plate 120, allowing the connecting plate 120 to be installed on the base 11 in the manner described above. The nut 50 remaining threadedly connected to the screw 60 also prevents loss of the nut 50.

Referring to FIG. 1, the connecting plate 120 is further provided with a knob plunger 14. The knob plunger 14 is a rotary plunger-type, manually operable positioning post. Referring to FIG. 2, the knob plunger 14 includes a knob portion 140 and a locking pin 141. The knob plunger 14 can flexibly control extension or retraction of the locking pin 141. The knob plunger 14 is used to more reliably fix the connecting plate 120 to the middle portion 110 of the base 11. An extended state of the locking pin 141 is a locked state. The middle portion 110 includes a hole 17, and the locking pin 141 is inserted into hole 17. This insertion locks the connection plate 120 to the base 11 and prevents the connection plate 120 from moving upward along the length direction of the base 11. The threaded cooperation between the nut 50 and the screw 60 constrains degrees of freedom of the connecting plate 120 relative to the base 11 in front, rear, left, and right directions. The knob plunger 14 constrains an up-down degree of freedom of the connecting plate 120, making the connecting plate 120 more reliably fixed to the base 11. The knob plunger 14 provides a rapid secondary lock mechanism. Based on the main fastening force provided by the nut 50, the constraint of the up-down degree of freedom by the locking pin 141 can effectively prevent loosening that may occur when the equipment is subjected to unexpected vibration or impact (e.g., in windy conditions), further enhancing long-term use safety and reliability.

When the knob portion 140 is pulled outward, the locking pin 141 retracts, separating the locking pin 141 from the hole 17. At this time, the knob plunger 14 is in an unlocked state. When the pulling force on the knob portion 140 is released, the locking pin 141 automatically returns to the extended state under the force of a built-in spring in the knob plunger 14, placing the knob plunger 14 in the locked state. Additionally, when the knob portion 140 is pulled outward and rotated by 30 degrees, the locking pin 141 can be kept in the unlocked state. In this state, after releasing the pulling force on the knob portion 140, the locking pin 141 will not extend. Rotating the knob portion 140 again by 30 degrees will cause the locking pin 141 to return to the extended state under the force of the built-in spring in the knob plunger 14.

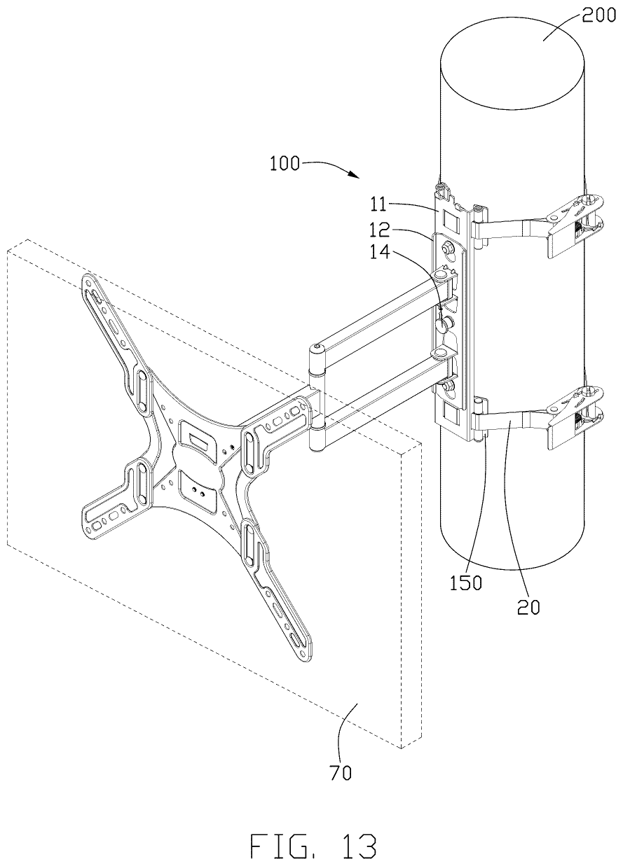

Referring to FIG. 2, when needing to install the mounting bracket 100 on the standing object 200, first, place the base 11 against the surface of the standing object 200. Then, pass the strap body 21, which is threaded through the base 11, around the standing object 200 and through the tightener 23. Subsequently, tighten the strap body 21 to bind the base 11 to the standing object 200. Next, align the large arc hole of the keyhole slot 123 with the screw 60 on the base 11. Push the connecting plate 120 toward the standing object 200 in the direction indicated by arrow a in FIG. 2, causing the screw 60 to pass through the large arc hole of the keyhole slot 123. After the screws 60 at the upper and lower ends of the base 11 have passed through the keyhole slots 123, press down the connecting plate 120 in the direction of arrow b in FIG. 2, causing the screw 60 to pass through the small arc hole of the keyhole slot 123. Finally, tighten the nut 50 on the screw 60, pressing the connecting plate 120 tightly against the base 11 through the nut 50. Because after installing a mountable object such as a display 70 (FIG. 13) on the mounting plate 30, the display 70 is subjected to a gravitational force in the same direction as arrow b in FIG. 2, and the nut 50 has already pressed the connecting plate 120 tightly against the base 11, the position of the mounting plate 30 is already very stable, unless subjected to an additional very large upward external force (e.g., manually applied force or force from strong wind). However, such an upward external force generally does not exist. If the locking pin 141 is inserted into the hole 17, the position of the mounting plate 30 relative to the base 11 is completely fixed, enhancing reliability. Of course, when using the knob plunger 14 for locking, the tightening of the nut 50 can also be performed after the locking pin 141 is inserted into the hole 17. As described above, after the nut 50 presses the connecting plate 120 against the base 11, the connecting plate 120 can be reliably fixed to the base 11, and at this time locking via the knob plunger 14 may be omitted.

Without locking via the knob plunger 14, when needing to remove the mounting plate 30, simply loosen the nut 50, then push the connecting plate 120 upward (opposite to the direction of arrow b in FIG. 2), and then pull the connecting plate 120 in the direction opposite to arrow a (opposite to the direction of arrow b in FIG. 2). If the knob plunger 14 was used for locking, only an additional step of unlocking via the knob plunger 14 is required.

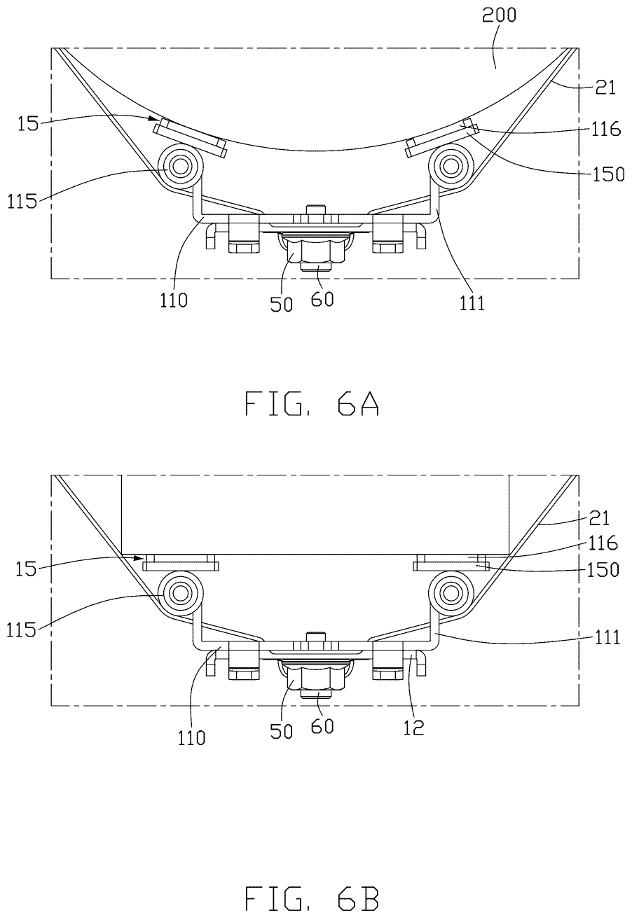

Referring to FIGS. 6(a) and 6(b), the board 150 can be adapted for a standing object 200 having an arc shaped surface or a square surface, which makes the base 11 more reliably fixed to the standing object 200.

For the base 11, designs in current related technologies typically have the side portion 111 bent inward relative to the middle portion 110, i.e., an angle between the side portion 111 and the middle portion 110 is less than 90°. As known to the inventor, in related art, the side portion 111 directly contacts a surface of the standing object 200. If the side portion 111 is bent outward relative to the portion 110 (i.e., the angle between the side portion 111 and the middle portion 110 is greater than 90°), after the strap body 21 applies a relatively large binding force to the connecting body 151, the side portion 111 tends to continue bending outward relative to the middle portion 110. This would increase the angle between the side portion 111 and the middle portion 110 beyond a set value, causing fracture at the connection between the side portion 111 and the middle portion 110, reducing the reliability of the mounting bracket 100. Selecting a sheet metal part as the base 11 is a good choice, and the angle between the side portion 111 and the middle portion 110 in many sheet metal parts is 90°. When using such a sheet metal part in the context of the mounting bracket 100, if the angle between the side portion 111 and the middle portion 110 needs to be less than 90°, secondary processing on the side plate portion 111 is often required to make this angle less than 90°.

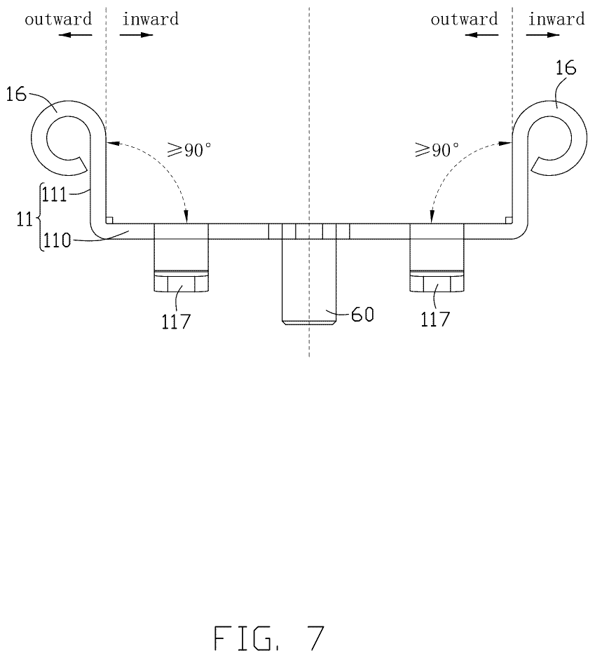

Referring to FIG. 6, in this embodiment, the side portion 111 does not directly contacts the surface of the standing object 200. Instead, contact with the surface of the standing object 200 is made through the board 150. The angle of the board 150 can be flexibly adjusted. Therefore, referring to FIG. 7, the angle between the side portion 111 and the middle portion 110 can be designed to be greater than or equal to 90°, and is not limited to less than 90°. Thereby, when a sheet metal part is to be used in the mounting bracket 100, the angle can often be directly selected as 90°. In many cases, this eliminates the need for secondary processing on the side portion 111. The strap body 21 exerts pressure on the connecting body 151 instead of on the side portion 111, therefore, the side portion 111 is hardly likely to deform.

Referring to FIG. 4, the base 11 comprises a middle portion 110 and two side portions 111, the middle portion 110 is an elongated rectangular main plate, and upper and lower ends of the middle portion 110 are each provided with a pair of elongated first holes 113 arranged in parallel and spaced apart; each of the two side portions 111 is bent from left and right side edges of the middle portion 110, and upper and lower ends of each side portion 111 are wound outward to form one winding structure 16, such that the base 11 has four winding structures 16 in total, respectively located at four corner positions of the base 11.

Each of the at least two active pieces 15 is rotatably mounted on the winding structures 16 in a one-to-one correspondence, each winding structure 16 comprises an upper portion and a lower portion spaced from the upper portion, a notch 1141 is formed between the upper portion and the lower portion, and after the active pieces 15 are mounted on the winding structures 16, a second hole 114 is formed at the position of the notch 1141.

The at least one strap 20 comprises two straps 20, one strap 20 sequentially passes through the pair of first holes 113 at the upper end of the middle portion 110 and the two second holes 114 at the upper ends of the two side portions 111, and the other strap 20 sequentially passes through the pair of first holes 113 at the lower end of the middle portion 110 and the two second holes 114 at the lower ends of the two side portions 111.

In summary, the mounting bracket 100 enables simple and quick installation of objects such as televisions and speakers on different standing object 200 without damaging the standing object 200, by first installing the base 11 and then installing the connecting plate 120 onto the base 11 in a quick-installation manner.

Clearly, the embodiments described above are only part of the embodiments of this application, not all of them. The drawings show relatively good embodiments of this application but do not limit the patent scope of this application. This application can be implemented in many different forms. On the contrary, the purpose of providing these embodiments is to make the understanding of the disclosure of this application more thorough and comprehensive.

Furthermore, persons of ordinary skill in the art should understand that the above embodiments are only used to illustrate this application and are not intended to limit this application. As long as within the essential spirit and scope of this application, appropriate changes and modifications to the above embodiments fall within the scope of disclosure of this application.

What is claimed is:

1. A display mounting bracket, for mounting a display to a standing object, the display mounting bracket comprising:
a base;
a mounting plate coupled to the base, and configured to mount the display; wherein the mounting plate is connected to an arm, and the arm is rotatably attached to a connecting plate, the connecting plate is opposite the base and detachably connected to the base; and
at least two active pieces, each rotatably attached to the base via a pivot shaft and configured to directly abut against a surface of the standing object.

2. The display mounting bracket according to claim 1, further comprising:
at least one strap configured for cooperating with the base and the at least two active pieces to detachably fix the display mounting bracket on the standing object;
wherein each of the at least one strap is detachably connected to the at least two active pieces, and in a condition that the at least one strap is bound on the standing object, the at least two active pieces are bound on the standing object and are pressed by the at least one strap.

3. The display mounting bracket according to claim 2, wherein
the base comprises a middle portion and two side portions; the middle portion has a first hole;
each of the two side portions is wound outward to form at least one winding structure;
each of the at least two active pieces is rotatably mounted on the at least two winding structures;
each of the at least two winding structures has a notch, and a second hole is formed at the notch after the at least two active pieces mounting;
the at least one strap passes through the first hole and the second hole;
each of the at least one strap has a tightener configured to adjust a tension force of the at least one strap.

4. The display mounting bracket according to claim 3, wherein:
an angle between each of the two side portions and the middle portion is greater than or equal to 90 degrees.

5. A mounting bracket for mounting a mountable object to a standing object, the mounting bracket comprising:
a base;
a mounting plate coupled to the base and configured to mount the mountable object; and,
at least two active pieces, each rotatably attached to the base via a pivot shaft and configured to abut against a surface of the standing object;
wherein, a position of each of the at least two active pieces is adjustable to adapt a shape of the surface of the standing object.

6. The mounting bracket according to claim 5, further comprising:
at least one strap configured for cooperating with at least one of the base and the at least two active pieces to detachably fix the mounting bracket on the standing object;
wherein each of the at least one strap is detachably connected to the at least two active pieces, and in a condition that the at least one strap is bound on the standing object, the at least two active pieces are self-adjustable to rotate relative to the base so as to engage with the surface of the standing object.

7. The mounting bracket according to claim 5, wherein
the base comprises a main portion to which the mounting plate is connected and a side portion bent from each of two sides of the main portion, the at least two active pieces are rotatably attached to two side portions, the main portion and the two side portions are spaced away from the surface of the standing object.

8. The mounting bracket according to claim 7, wherein
a first hole is defined in the main portion;
a second hole is defined in each of the two side portions;
at least one strap passes through the first hole and the second hole, the at least two active pieces are located between the at least one strap and the surface of the standing object.

9. The mounting bracket according to claim 7, wherein
each of the at least two active pieces comprises a board pivoted on each of the two side portions and spaced away from the main portion, the board having a first surface for contacting the surface of the standing object.

10. The mounting bracket according to claim 9, wherein
each of the at least two active pieces further comprises a connecting body fixedly connected to the board, and each connecting body is sleeved on the respective pivot shaft, enabling the board to rotate around the respective pivot shaft to adjust an angle of the first surface relative to the base.

11. The mounting bracket according to claim 10, wherein
each of the two side portions has an end wound outward to form a winding structure;
the pivot shaft is located on the winding structure.

12. The mounting bracket according to claim 11, wherein
the winding structure has a notch.

13. The mounting bracket according to claim 9, wherein
a pad is set on the board so as to increase friction between the board and the surface of the standing object; and
the pad is softer than the board.

14. The mounting bracket according to claim 7, wherein
the at least two active pieces comprise a first piece, a second piece, a third piece and a fourth piece, the first, second, third and fourth pieces are attached to four corners of the base with being spaced from the main portion.

15. The mounting bracket according to claim 14, further comprising:
at least one strap configured for cooperating with at least one of the base and the at least two active pieces to detachably fix the mounting bracket on the standing object;
wherein the at least one strap comprises a first strap and a second strap, the first strap is attached to a first end of the base and adjacent to the first piece and the second piece, the first strap presses the first piece and the second piece toward the standing object, the second strap is attached to a second end of the base and adjacent to the third piece and the fourth piece, the second strap presses the third piece and the fourth piece toward the standing object.

16. The mounting bracket according to claim 5, wherein
the mounting plate is connected to the base by a connecting plate, the connecting plate is opposite the base and detachably connected to the base;
the base comprises a screw;
the connecting plate comprises a keyhole slot;
the connecting plate is capable of being hooked onto the screw through the keyhole slot and fastened by a nut.

17. The mounting bracket according to claim 16, wherein
the base comprises a hole;
the connecting plate is provided with a knob plunger;
a locking pin of the knob plunger is inserted into the hole.

18. The mounting bracket according to claim 17, wherein
the base and the connecting plate have has an elongated shape, and a length of the connecting plate is less than a length of the base;
when the connecting plate is connected to the base, the connecting plate fits against the base, and the connecting plate is located between an upper end and a lower end of the base.

19. A mounting bracket for mounting a mountable object to a standing object, the mounting bracket comprising:
a base, the base not directly contacting a surface of the standing object;
a mounting plate coupled to the base and configured to mount the mountable object; and
at least two active pieces, each rotatably attached to the base via a pivot shaft and configured to directly abut against a surface of the standing object; and
at least one strap configured for cooperating with the base and the at least two active pieces to detachably fix the mounting bracket on the standing object.

20. The mounting bracket according to claim 19, wherein,
the base comprises a middle portion and two side portions, each of the two side portions is wound outward to form a winding structure, and each of the at least two active pieces is rotatably installed on the winding structure;
the mounting plate is connected to the middle portion; and
the at least one strap is configured to bind the base to the standing object and press against the at least two active pieces towards the standing object.
